(19) United States
(12) Patent Application Publication
(10) Pub. No.: US 2026/0058102 A1
(43) Pub. Date: Feb. 26, 2026

(54) PLASMA SUPPLY APPARATUS AND SUBSTRATE TREATMENT APPARATUS INCLUDING THE SAME

(71) Applicant: Samsung Electronics Co., Ltd., Suwon-si (KR)

(72) Inventors: HYUN BAE KIM, Suwon-si (KR); Seongcheol Kim, Suwon-si (KR); KYUNG-SUN KIM, Suwon-si (KR); Nam Kyun Kim, Suwon-si (KR); SANG KI NAM, Suwon-si (KR); HYUNJAE LEE, Suwon-si (KR); SEUNGBIN LIM, Suwon-si (KR); Hyunhak Jeong, Suwon-si (KR)

(21) Appl. No.: 19/035,067

(22) Filed: Jan. 23, 2025

(30) Foreign Application Priority Data
Aug. 20, 2024 (KR) 10-2024-0111080

(51) Int. Cl. H01J 37/32

(52) U.S. Cl. CPC H01J 37/32422; H01J 37/3222; H01J 37/32229; H01J 37/32201

(57) ABSTRACT

A substrate treatment apparatus including: a plasma supply apparatus configured to supply plasma, wherein the plasma supply apparatus includes a plasma supply portion configured to supply the plasma into a chamber having a processing space in which a substrate is processed; and a radical control portion configured to control the quantity of radicals in the processing space, wherein the plasma supply portion includes a plasma chamber located outside the processing space and having a space in which the plasma is generated.

### CROSS-REFERENCE TO RELATED APPLICATION

This application claims priority under 35 U.S. C. § 119 to Korean Patent Application No. 10-2024-0111080, filed on Aug. 20, 2024, in the Korean Intellectual Property Office, the disclosure of which is incorporated by reference herein in its entirety.

### TECHNICAL FIELD

The present disclosure relates to a plasma supply apparatus and a substrate treatment apparatus including the same, and more particularly, to a plasma supply apparatus capable of controlling the quantity of radicals and a substrate treatment apparatus including the same.

### Discussion of Related Art

As semiconductor line widths become finer, semiconductor patterns are developing into narrow and deep high aspect ratio forms.

It is required to control the quantity and ratio of ions and radicals included in the plasma to shorten the process time when processing a substrate using plasma, improving productivity in such a high aspect ratio process.

At this time, the quantity of ions generated can be independently controlled by controlling the size of the voltage of the power applied to generate plasma.

And, pressure control within the chamber is essential for controlling the quantity of radicals generated. However, it is difficult to control the quantity of radicals generated, since a low pressure close to vacuum pressure is required in the process for forming a high aspect ratio pattern.

### SUMMARY

Embodiments of the present disclosure provide a plasma supply apparatus capable of controlling the quantity of radicals and a substrate treatment apparatus including the same.

According to an example embodiment, there is provided a plasma supply apparatus including: a plasma supply portion configured to supply plasma into a chamber having a processing space in which a substrate is processed; and a radical control portion configured to control a quantity of radicals in the processing space, wherein the radical control portion includes: a plasma chamber located outside the processing space and having a space in which the plasma is generated; a magnetron configured to generate microwaves; a waveguide connected between the magnetron and the plasma chamber and configured to cause the microwaves to be transmitted between the magnetron and the plasma chamber; a reaction gas supply portion configured to supply a reaction gas into the plasma chamber, and control an internal pressure of the plasma chamber; and a radical supply connection portion connecting the plasma chamber and the chamber to be in communication with each other.

According to an example embodiment, there is provided a substrate treating apparatus including: a chamber having a processing space in which a substrate is processed; a stage supporting the substrate in the processing space; a plasma supply apparatus configured to supply plasma to the processing space and control a quantity of radicals in the processing space, wherein the plasma supply apparatus includes: a plasma supply portion configured to supply the plasma to the processing space; and a radical control portion configured to control the quantity of the radicals in the processing space, wherein the plasma supply portion includes: a gas supply portion configured to supply a treatment gas into the processing space; and a plasma generation portion configured to convert the treatment gas into the plasma, wherein the plasma generation portion includes: an antenna above the chamber; and a source power supply configured to apply high-frequency power to the antenna, wherein the radical control portion includes: a plasma chamber located outside the processing space and having a space in which the plasma is generated; a magnetron configured to generate microwaves; a waveguide connected between the magnetron and the plasma chamber and configured to cause the microwaves to be transmitted between the magnetron and the plasma chamber; a reaction gas supply portion configured to supply a reaction gas into the plasma chamber, and control the internal pressure of the plasma chamber; and a radical supply connection portion connecting the plasma chamber and the chamber to be in communication with each other.

According to an example embodiment, there is provided a substrate treating apparatus including: a chamber having a processing space in which a substrate is processed; a stage supporting the substrate in the processing space; a plasma supply apparatus configured to supply plasma to the processing space and control a quantity of radicals in the processing space, wherein the plasma supply apparatus includes: a plasma supply portion configured to supply the plasma into the processing space; and a radical control portion configured to control the quantity of the radicals in the processing space, wherein the plasma supply portion includes: a gas supply portion configured to supply a treatment gas into the processing space; and a plasma generation portion configured to convert the treatment gas into the plasma, wherein the plasma generation portion includes: an upper electrode above a substrate in the processing space; a lower electrode facing the upper electrode and positioned below the substrate; and a source power supply configured to apply high-frequency power to at least one of the upper electrode and the lower electrode, wherein the treatment gas is supplied between the upper electrode and the lower electrode, wherein the radical control portion includes: a plasma chamber located outside the processing space and having a space in which the plasma is generated; a magnetron configured to generate microwaves; a waveguide connected between the magnetron and the plasma chamber and configured to cause the microwaves to be transmitted between the magnetron and the plasma chamber; a reaction gas supply portion configured to supply a reaction gas into the plasma chamber, and control an internal pressure of the plasma chamber; and a radical supply connection portion configured to connect the plasma chamber and the chamber to be in communication with each other.

### BRIEF DESCRIPTION OF DRAWINGS

The above and other features of the present disclosure will be more clearly understood from the following detailed description, taken in conjunction with the accompanying drawings.

FIG. 1 is a cross-sectional view illustrating a substrate treatment apparatus according to an example embodiment of the present disclosure.

FIG. 2 is a drawing illustrating an example of the radical control portion illustrated in FIG. 1.

FIG. 3 is a cross-sectional view illustrating a substrate treatment apparatus according to an example embodiment of the present disclosure.

FIG. 4 is a plan view illustrating the upper surface of the window of FIG. 3.

FIG. 5 is a cross-sectional view illustrating a substrate treatment apparatus according to an example embodiment of the present disclosure.

FIG. 6 is a plan view illustrating the upper surface of the window of FIG. 5.

FIG. 7 is a cross-sectional view illustrating a substrate treatment apparatus according to an example embodiment of the present disclosure.

FIG. 8 is a cross-sectional view illustrating a substrate treatment apparatus according to an example embodiment of the present disclosure.

FIGS. 9 to 15 are drawings illustrating process simulation results of a conventional substrate treatment apparatus and a substrate treatment apparatus according to example embodiments of the present disclosure.

### DETAILED DESCRIPTION OF THE EMBODIMENTS

Hereinafter, embodiments of the present disclosure will be described in detail and with sufficient clarity for those skilled in the art to easily implement the invention. Like reference characters refer to like elements throughout.

A substrate treatment apparatus that etches a substrate using plasma is described in the embodiments of the present disclosure. However, the present disclosure is not limited thereto and can be applied to various apparatuses that require control of the quantity of radicals used for substrate processing.

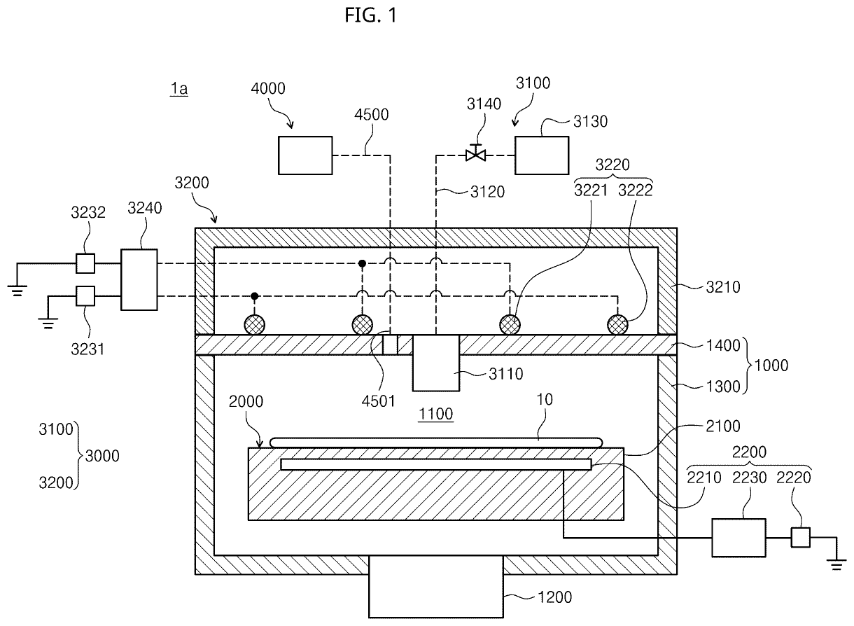

FIG. 1 is a cross-sectional view illustrating a substrate treatment apparatus according to an example embodiment of the present disclosure.

Referring to FIG. 1, the substrate treatment apparatus 1a may include a chamber 1000, a stage 2000, and a plasma supply apparatus 3000, 4000.

The substrate treatment apparatus 1a may perform a process on a substrate 10 using plasma. The substrate treatment apparatus 1a according to example embodiments of the present disclosure may control the quantity of radicals supplied when performing a process on the substrate 10.

The substrate 10 may be provided as a wafer or glass, etc. The substrate 10 may have a disc structure of various diameters. However, the shape of the substrate 10 is not limited thereto and may be provided in other shapes and/or various sizes.

The chamber 1000 may include a processing space 1100 therein. The substrate 10 may be processed in the processing space 1100. The chamber 1000 may isolate the stage 2000 from the external environment to create a vacuum environment in the processing space 1100. In addition, the chamber 1000 may include a pumping connection 1200 that is connected to a vacuum system, and openings and/or connections formed in a part that are connected to a plasma supply portion 3000 and/or a radical control portion 4000. The sizes and structures of the pumping connection 1200, the openings, and the connections may vary.

The vacuum system connected to the pumping connection 1200 may include a high vacuum pump such as a turbo-molecular pump, a low vacuum pump such as a dry pump, and/or various valves. The vacuum system may discharge air inside the chamber 1000 to create a vacuum environment inside the processing space 1100. In addition, the vacuum system may discharge reaction byproducts generated during the process and gases remaining in the processing space 1100 to the outside.

According to example embodiments, the chamber 1000 may include a housing 1300 and a window 1400.

The housing 1300 may have an internal space having an open upper surface inside. The internal space of the housing 1300 may be provided as a processing space 1100 where a substrate is processed. The housing 1300 may be provided with a metal material. The housing 1300 may be provided with an aluminum material. The housing 1300 may be grounded. The pumping connection 1200 connected to a vacuum system may be on the floor surface of the housing 1300. A liner that protects the inner surface of the housing 1300 from arc discharge and is replaceable may be provided in the housing 1300.

A window 1400 may be provided as an upper wall of the chamber 1000. According to example embodiments, the window 1400 may cover the open upper surface of the housing 1300. The window 1400 may be provided in a plate shape. The window 1400 may seal the inner space of the housing 1300. The window 1400 may include a dielectric substance window.

The stage 2000 may support the substrate 10 within the processing space 1100. The stage 2000 may include an electrostatic chuck (ESC) that may fix and support the substrate 10 by electrostatic force. The stage 2000 may control the temperature and temperature uniformity of the substrate 10.

According to example embodiments, the stage 2000 may include an electrostatic chuck 2100 and a bias voltage generator 2200. The stage 2000 may be provided to be spaced above and apart from the floor surface of the housing 1300 in the inner space of the housing 1300.

A substrate 10 may be placed on the upper surface of the electrostatic chuck 2100. The electrostatic chuck 2100 may fix the substrate 10 with electrostatic force. Various components required for the process, such as a heater for heating the substrate 10 and/or a cooling portion for cooling the substrate 10, may be provided inside the electrostatic chuck 2100.

The bias voltage generator 2200 may apply a self-bias voltage to the substrate 10 placed on the electrostatic chuck 2100. The self-bias voltage controls ions included in the plasma within the processing space 1100. According to example embodiments, the bias voltage generator 2200 may include a bias electrode 2210, a bias power supply 2220, and a bias matching portion 2230.

The bias electrode 2210 may be embedded in the electrostatic chuck 2100. The bias power supply 2220 may generate a RF (Radio Frequency) power for applying a bias signal for plasma control to the bias electrode 2210. The bias power supply 2220 may be grounded. The bias matching portion 2230 may be provided between the electrostatic chuck 2100 and the bias power supply 2220 and match impedance. The process effect of ions included in the plasma on the substrate 10 may be controlled by controlling the power of the bias power supply 2220.

The plasma supply apparatus 3000, 4000 may supply plasma to the processing space 1100 and control the quantity of radicals in the processing space 1100. The plasma supply apparatus 3000, 4000 may include a plasma supply portion 3000 and a radical control portion 4000.

The plasma supply portion 3000 may supply plasma to the processing space 1100. The plasma reacts with the substrate 10 to treat the substrate 10. According to example embodiments, the plasma supply portion 3000 may include a gas supply portion 3100 and a plasma generation portion 3200.

The gas supply portion 3100 may inject a treating gas or a process gas into the processing space 1100 through an inlet formed in the form of a nozzle or a showerhead. The gas supply portion 3100 may supply the gas to a single zone or a plurality of zones of the processing space 1100 to inject uniformly the treatment gas or process gas into the processing space 1100. The gas supplied by the gas supply portion 3100 may be converted into plasma by the plasma generation portion 3200 within the processing space 1100. Alternatively, the gas supplied by the gas supply portion 3100 may be supplied to the processing space 1100 in a state in which it is converted into plasma by the plasma generation portion 3200. Hereinafter, the gas supplied by the gas supply portion 3100 is described as a treatment gas.

According to example embodiments, the gas supply portion 3100 may include a gas supply nozzle 3110, a gas supply line 3120, and a gas storage 3130. The gas supply nozzle 3110 may be installed at the center of the window 1400, and may extend into the processing space 1100. An injection port is formed on the bottom surface of the gas supply nozzle 3110. The injection port may be at the bottom of the window 1400 and supply a treatment gas into the chamber 1000. The number and installation location of the gas supply nozzle 3110 may be various as needed.

The gas supply line 3120 may connect the gas supply nozzle 3110 and the gas storage 3130. The gas supply line 3120 may supply the treatment gas stored in the gas storage 3130 to the gas supply nozzle 3110. A valve 3140 may be installed in the gas supply line 3120. The valve 3140 may open and close the gas supply line 3120 and control the flow rate of the treatment gas supplied through the gas supply line 3120.

The plasma generation portion 3200 may generate plasma for processing the substrate 10 in the processing space 1100. The plasma generation portion 3200 may generate plasma from gas supplied into the chamber 1000 by the gas supply portion 3100. The plasma generation portion 3200 may be provided as a reactive ion etching source. For example, the reactive ion etching source may be provided as an inductively coupled plasma (ICP) source formed in the form of a coil-based antenna or a capacitively coupled plasma (CCP) source formed in the form of a plate, etc.

The plasma generation portion 3200 may be provided as an ICP (Inductively Coupled Plasma) type. According to example embodiments, the plasma generation portion 3200 may include an antenna room 3210, an antenna 3220, a source power supplies 3231, 3232, and a source matching portion 3240.

The antenna room 3210 may be provided in a cylindrical shape having an open bottom. The antenna room 3210 may have a space for accommodating an antenna 3220 therein. The antenna room 3210 may be provided to have a diameter corresponding to the diameter of the chamber 1000. The bottom of the antenna room 3210 may be detachably attached to a window 1400.

The antenna 3220 may be inside the antenna room 3210. The antenna 3220 may include a plurality of antenna coils 3221, 3222 provided in a ring shape. According to example embodiments, the antenna 3220 may include a first antenna coil 3221 and a second antenna coil 3222. The first antenna coil 3221 may be at a position that surrounds the center of a substrate 10 placed on a stage 2000 within a processing space 1100 when viewed from above. The second antenna coil 3222 may have a structure that surrounds the outer side of the first antenna coil 3221. However, the antenna 3220 is not limited to including two antenna coils and may include more antenna coils.

Each of the source power supplies 3231, 3232 may be a RF (Radio Frequency) power source and may supply RF power to each of the first antenna coil 3221 and the second antenna coil 3222. The source power supplies 3231, 3232 may be provided corresponding to each of the first antenna coil 3221 and the second antenna coil 3222. For example, the source power supply 3232 may supply RF power to the first antenna coil 3221, and the source power supply 3231 may supply RF power to the second antenna coil 3222. The source power supplies 3231, 3232 may apply RF power having different frequencies and/or different power magnitudes to each of the first antenna coil 3221 and the second antenna coil 3222. Alternatively, the source power supplies 3231, 3232 may apply RF power having the same frequencies and/or the same power magnitudes to each of the first antenna coil 3221 and the second antenna coil 3222. The source power supplies 3231, 3232 may be outside the chamber 1000. The antenna 3220 to which power is applied may form an electromagnetic field in the processing space 1100 of the chamber 1000. The treatment gas in the processing space 1100 is converted into a plasma state by the electromagnetic field. The quantity of plasma generated may be controlled by controlling the power of the source power supplies 3231, 3232.

The source matching portion 3240 may be between each of the antenna coils 3221, 3222 and the source power supplies 3231, 3232 to match the impedance.

The radical control portion 4000 may supply radicals to the processing space 1100 to control the quantity of radicals in the processing space 1100. The radical control portion 4000 may be provided in a remote plasma manner that generates radicals outside the chamber 1000 and supplies the generated radicals to the processing space 1100.

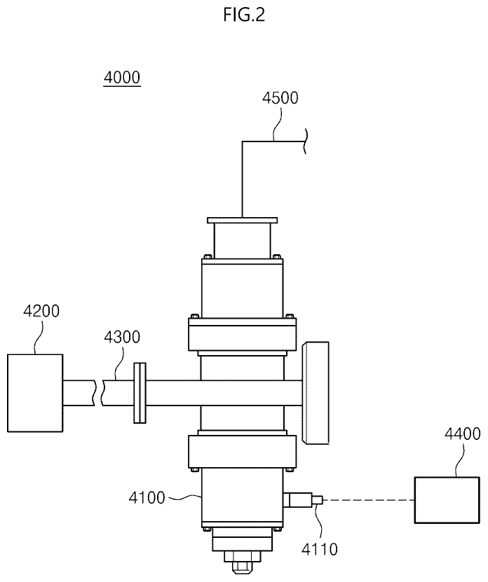

FIG. 2 is a drawing illustrating an example of the radical control portion illustrated in FIG. 1.

Referring to FIG. 2, the radical control portion 4000 may be provided in a manner of generating plasma using microwaves. According to example embodiments, the radical control portion 4000 may include a plasma chamber 4100, a magnetron 4200, a waveguide 4300, a reaction gas supply portion 4400, and a radical supply connection portion 4500.

The plasma chamber 4100 may be outside the chamber 1000. A space in which plasma is generated may be formed inside the plasma chamber 4100. The magnetron 4200 may be connected to the plasma chamber 4100 by the waveguide 4300. And a gas inlet 4110 may be formed on one side of the plasma chamber 4100.

The magnetron 4200 generates microwaves for generating plasma. The microwave is transmitted into the plasma chamber 4100 through the waveguide 4300.

The reaction gas supply portion 4400 may supply the reaction gas into the plasma chamber 4100 through the gas inlet 4110. The reaction gas inside the plasma chamber 4100 is converted into plasma by the microwave. The plasma generated inside the plasma chamber 4100 includes radicals. The reaction gas supply portion 4400 may control the pressure inside the plasma chamber 4100 by controlling the pressure of the gas supplied to the plasma chamber 4100.

The radical supply connection portion 4500 may connect the plasma chamber 4100 and the chamber 1000 to bring the plasma chamber 4100 and the chamber 1000 in communication with each other. The plasma including the radicals generated inside the plasma chamber 4100 may be supplied to the processing space 1100 through the radical supply connection portion 4500. For example, the plasma chamber 4100 and the chamber 1000 may be fluidly connected with each other through the radical supply connection portion 4500. As used herein, items described as being “fluidly connected” are configured such that a liquid or gas can flow, or be passed, from one item to the other. According to example embodiments, one end of the radical supply connection portion 4500 may be connected to the other side of the plasma chamber 4100, and the other end 4501 of the radical supply connection portion 4500 may be connected to the window 1400. A nozzle may be at a position at the window 1400 where the other end 4501 is connected, and radicals generated in the radical control portion 4000 may be supplied into the chamber 1000 from a position at the bottom surface of the window 1400 corresponding to the position where the other end 4501 is connected. The other end 4501 may be connected to a position at the window 1400 facing a central area of a substrate 10 placed on a stage 2000. The central region may be a region having a diameter range from the center of the substrate 10 to a position spaced apart from the outer circumference of the substrate 10. In this case, the radical supply connection portion 4500 may be connected to one position at the window 1400. When the gas supply nozzle 3110 is positioned at a position facing the center of the substrate 10 placed on the stage 2000, the other end 4501 may be outside the position of the gas supply nozzle 3110. Alternatively, when the gas supply nozzle 3110 is not positioned at a position facing the center of the substrate 10 placed on the stage 2000, the other end 4501 may be positioned at a position facing the center of the substrate 10 placed on the stage 2000.

The quantity of radicals generated in the plasma chamber 4100 may be controlled by controlling the power of the magnetron 4200 for plasma generation and/or the pressure of the reaction gas supplied by the reaction gas supply portion 4400.

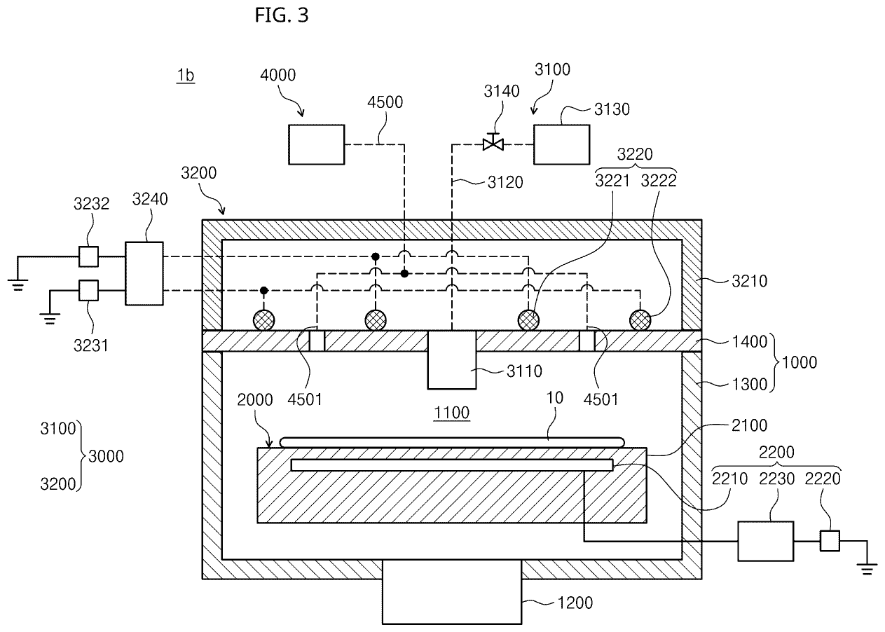

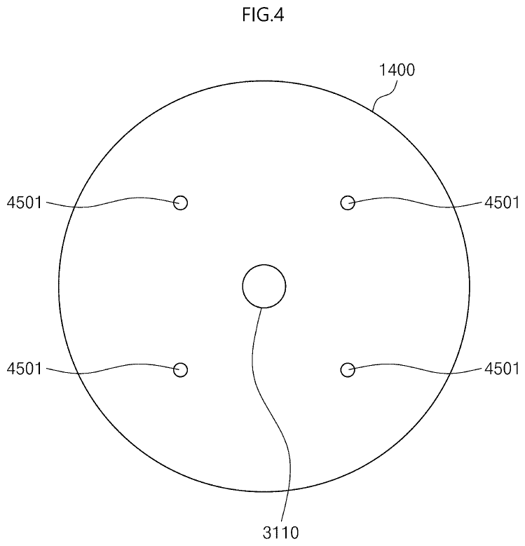

FIG. 3 is a cross-sectional view illustrating a substrate treatment apparatus according to an example embodiment of the present disclosure. FIG. 4 is a plan view illustrating the upper surface of the window of FIG. 3. Hereinafter, the redundant description of the previous embodiments will be omitted, and the following description will be based on differences from the previous embodiments.

Referring to FIG. 3 and FIG. 4, in the substrate treatment apparatus 1b, the other end 4501 of the radical supply connection portion 4500 may be connected to various positions of the window 1400 as desired. And the radical generated by the radical control portion 4000 may be supplied into the chamber 1000 from the position where the other end 4501 is connected. In addition, the radical supply connection portion 4500 may be branched to have a plurality of the other ends 4501. And each of the other ends 4501 of the radical supply connection portion 4500 may be connected to a different area of the window 1400, respectively. Therefore, radicals generated in the radical control portion 4000 may be supplied into the chamber 1000 from multiple positions on the bottom surface of the upper wall of the chamber 1000. The number and the connection position of the other ends 4501 at the window 1400 may be set by test operation and/or simulation.

For example, the other ends 4501 may be arranged spaced apart from each other along the outer circumference direction of the substrate 10 in the area of the window 1400 facing the edge area of the substrate 10 placed on the stage 2000. The edge area may be an area located further outside the substrate 10 than the central area and have a diameter range including the outer circumference of the substrate 10. Therefore, the radicals generated by the radical control portion 4000 may be supplied into the chamber 1000 from the positions of the bottom surface of the window 1400 facing the edge area of the substrate 10 placed on the stage 2000.

Other configurations, structures and functions of the substrate treatment apparatus 1b of FIG. 3 may be provided identically to or substantially the same as the substrate treatment apparatus 1a of FIG. 1.

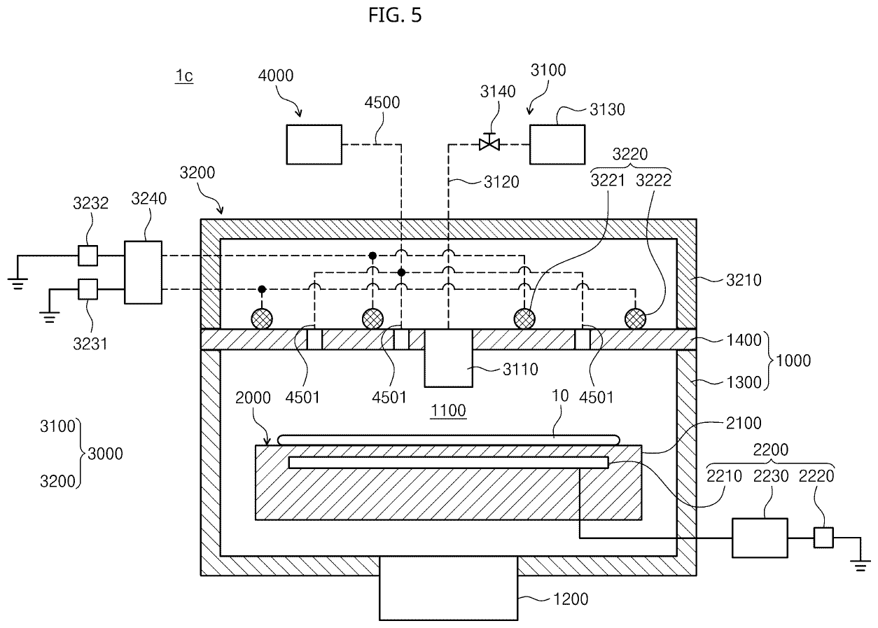

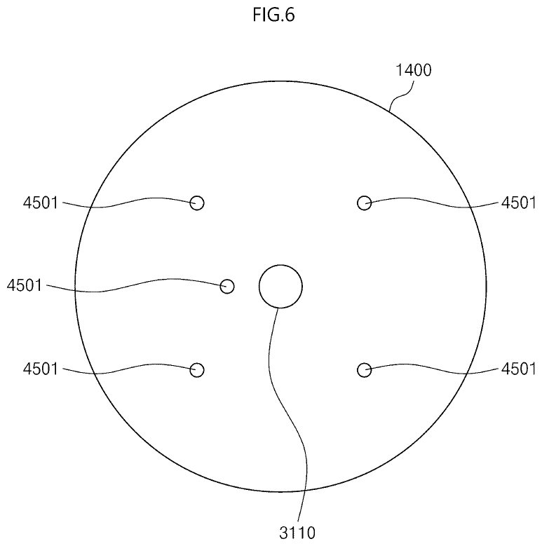

FIG. 5 is a cross-sectional view illustrating a substrate treatment apparatus according to an example embodiment of the present disclosure. FIG. 6 is a plan view illustrating the upper surface of the window of FIG. 5. Hereinafter, the redundant description of the previous embodiments will be omitted, and the following description will be based on differences from the previous embodiments.

Referring to FIGS. 5 and 6, in the substrate treatment apparatus 1c, according to example embodiments, the branched other ends 4501 of the radical supply connection portion 4500 may be connected to the area of the window 1400 facing the central area and the edge area of the substrate 10 placed on the stage 2000. And the other ends 4501 of the radical supply connection portion 4500 connected to the area of the window 1400 facing the edge area of the substrate 10 placed on the stage 2000 may be arranged to be spaced apart from each other along the outer circumferential direction of the substrate 10. Accordingly, the radicals generated in the radical control portion 4000 may be supplied into the chamber 1000 from the positions on the bottom surface of the window 1400 facing the central area and the edge area of the substrate 10 placed on the stage 2000.

Other configurations, structures, and functions of the substrate treatment apparatus 1c of FIG. 5 may be provided identically to or substantially the same as the substrate treatment apparatus 1b of FIG. 3.

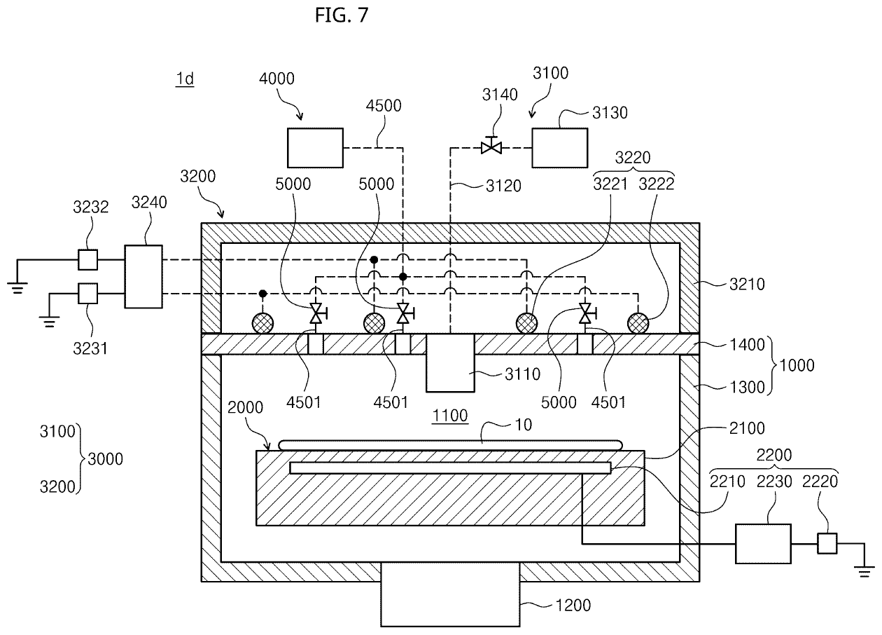

FIG. 7 is a cross-sectional view illustrating a substrate treatment apparatus according to an example embodiment of the present disclosure. Hereinafter, the redundant description of the previous embodiments will be omitted, and the following description will be based on differences from the previous embodiments.

Referring to FIG. 7, in the substrate treatment apparatus 1d, the radical supply connection portion 4500 may be provided with valves 5000 that control the opening/closing ratio of each of the other ends 4501. Each of the valves 5000 may independently control the opening/closing ratio of a corresponding one of the other ends 4501 of the radical supply connection portion 4500. Therefore, the substrate treatment apparatus 1d according to example embodiments may control the quantity of radicals supplied from the radical control portion 4000 to each area of the processing space 1100 by controlling the opening/closing ratio of each of the valves 5000.

Other configurations, structures, and functions of the substrate treatment apparatus 1d of FIG. 7 may be provided identically to or substantially the same as the substrate treatment apparatus 1c of FIG. 5.

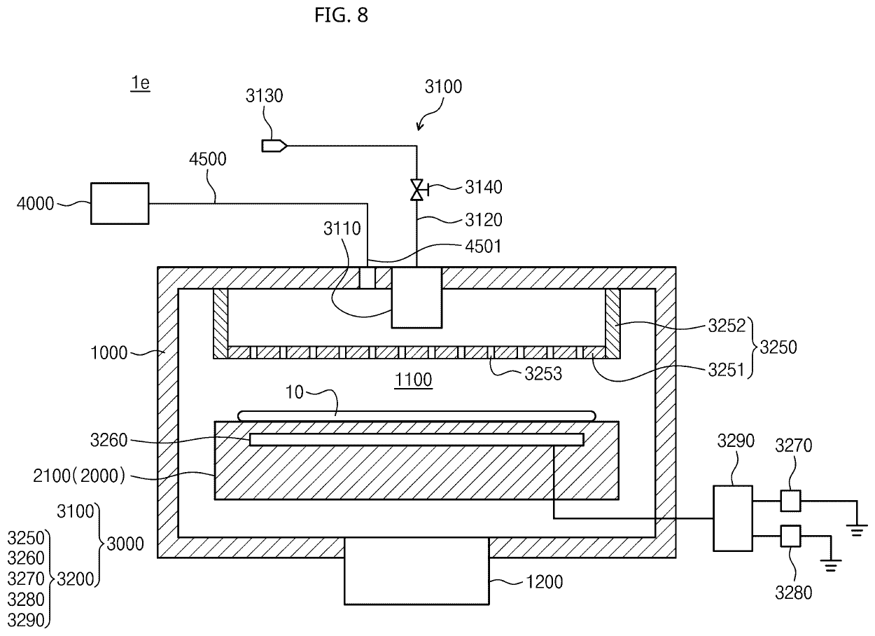

FIG. 8 is a cross-sectional view illustrating a substrate treatment apparatus according to an example embodiment of the present disclosure. Hereinafter, the redundant description of the previous embodiments will be omitted, and the following description will be based on differences from the previous embodiments.

Referring to FIG. 8, in the substrate treatment apparatus 1e, the inner space of the chamber 1000 may be provided as a processing space 1100 where a substrate treatment process is performed.

The stage 2000 may include an electrostatic chuck 2100. The stage 2000 may be spaced upward and apart from the floor surface of the chamber 1000 in the processing space 1100 of the chamber 1000.

According to example embodiments, the gas supply nozzle 3110 of the gas supply portion 3100 may be installed on the upper wall of the chamber 1000. Accordingly, the gas supplied by the gas supply portion 3100 may be supplied between the ceiling surface of the chamber 1000 and the shower head 3251, and then supplied to the space between the upper electrode 3250 and the lower electrode 3260 through the holes 3253 of the shower head 3251. The structure and method of installing the gas supply nozzle 3110 on the upper wall of the chamber 1000 may be the same as or similar to the structure and method of installing one of the gas supply nozzles 3110 of FIG. 1, FIG. 3, FIG. 5, and FIG. 7 on the window 1400.

The plasma generation portion 3200 may be provided as a CCP (Capacitively Coupled Plasma) type. According to example embodiments, the plasma generation portion 3200 may include the upper electrode 3250, the lower electrode 3260, a source power supply 3270, a bias power supply 3280, and a mixing matching portion 3290.

The upper electrode 3250 and the lower electrode 3260 may be provided to face each other in the vertical direction. The upper electrode 3250 may include the shower head 3251 and a ring assembly 3252.

The shower head 3251 is positioned opposite to the electrostatic chuck 2100. The shower head 3251 may be spaced downward and apart from the ceiling surface of the chamber 1000. The shower head 3251 may be provided with a larger diameter than the electrostatic chuck 2100. The holes 3253 for spraying gas are formed in the shower head 3251. According to example embodiments, the shower head 3251 may be provided with silicon. Optionally, the shower head 3251 may be provided with a metal material.

The ring assembly 3252 fastens the shower head 3251 to the ceiling surface of the chamber 1000. The ring assembly 3252 may surround the shower head 3251. The ring assembly 3252 may contact the shower head 3251 to be electrically connected to the shower head 3251. The ring assembly 3252 may tightly contact with the shower head 3251. The ring assembly 3252 may be provided with the same material as the shower head 3251.

The lower electrode 3260 may be within the electrostatic chuck 2100. According to example embodiments, the upper electrode 3250 may be grounded, and the lower electrode 3260 may be connected to the source power supply 3270. Alternatively, the upper electrode 3250 may be connected to a source power supply 3270, and the lower electrode 3260 may be grounded, optionally. In addition, the source power supply 3270 may be connected to both the upper electrode 3250 and the lower electrode 3260, optionally. The source power supply 3270 may apply RF power to the upper electrode 3250 and/or the lower electrode 3260. When the source power supply 3270 applies RF power to the upper electrode 3250 and/or the lower electrode 3260, the gas supplied between the upper electrode 3250 and the lower electrode 3260 is converted into plasma used in the substrate treatment process by the electromagnetic field generated between the upper electrode 3250 and the lower electrode 3260.

The bias power supply 3280 may be connected to the lower electrode 3260. Therefore, when the source power supply 3270 is connected to the lower electrode 3260, the source power supply 3270 and the bias power supply 3280 may be connected to the lower electrode 3260.

A mixing matching portion 3290 may mix the RF power of the source power supply 3270 and the RF power of the bias power supply 3280 applied to the lower electrode 3260. And, the mixing matching portion 3290 matches the impedance between the lower electrode 3260, and the source power supply 3270 and the bias power supply 3280.

Alternatively, when the source power supply 3270 is connected only to the upper electrode 3250, a matching portion that matches the impedance between the lower electrode 3260 and the bias power supply 3280 may be between the lower electrode 3260 and the bias power supply 3280.

According to example embodiments, the other end 4501 of the radical supply connection portion 4500 of the radical control portion 4000 may be connected to the upper wall of the chamber 1000. Accordingly, the radicals generated by the radical control portion 4000 may be supplied between the ceiling surface of the chamber 1000 and the shower head 3251, and then supplied to the space between the upper electrode 3250 and the lower electrode 3260 through the holes 3253 of the shower head 3251.

The structure and method of installing the radical supply connection portion 4500 on the upper wall of the chamber 1000 may be substantially the same as the structure and method of installing one of the radical supply connection portions 4500 of FIG. 1, FIG. 3, FIG. 5, and FIG. 7 on the window 1400.

Other configurations, structures, functions, etc. of the substrate treatment apparatus 1e of FIG. 8 may be provided the same as or similar to the substrate treatment apparatuses 1a, 1b, 1c, and 1d of FIG. 1, FIG. 3, FIG. 5, and FIG. 7, respectively.

FIGS. 9 to 15 are drawings illustrating process simulation results of a conventional substrate treatment apparatus and a substrate treatment apparatus according to example embodiments of the present disclosure.

The simulation was performed using a HPEM (Hybrid Plasma Equipment Model) simulation code.

The simulation of the substrate treatment apparatus of the present disclosure was set as the plasma generation portion 3200 is an etching apparatus of the inductively coupled plasma (ICP) source type such as the substrate treatment apparatus 1a of FIG. 1.

Other conditions of the simulation for the substrate treatment apparatus of the present disclosure are as follows.

The source power supply 3231 for the first antenna coil 3221 was set to 27 MHz and 300 W. And, the source power supply 3232 for the second antenna coil 3222 was set to 2 MHz and 300 W. The pressure in the processing space 1100 was set to 80 mTorr. The treatment gas was set to be as chlorine (Cl₂) gas and supplied to the processing space 1100 at 120 SCCM. In addition, the bias power supply 2220 was set to 875 Vpp.

In addition, the conditions for the radical control portion 4000 are as follows. The other end 4501 of the radical supply connection portion 4500 is set to be connected to a position on the upper wall of the chamber 1000 corresponding to the center of the substrate 10 placed on the stage 2000. In addition, 480 SCCM of chlorine (Cl₂) gas is supplied to the chamber 1000, and the internal pressure of the chamber 1000 is set to 1 Torr. In addition, the magnetron 4200 is set to a condition of a frequency of 2.45 GHz and 2 kW.

The simulation conditions of the conventional substrate treatment apparatus are as follows. In the case of the conventional substrate treatment apparatus, the radical control portion 4000 is not provided. In addition, the conditions of the simulation conditions for the substrate treatment apparatus of the present disclosure described above, excluding the conditions for the radical control portion 4000, were used for the simulation conditions of the conventional substrate treatment apparatus.

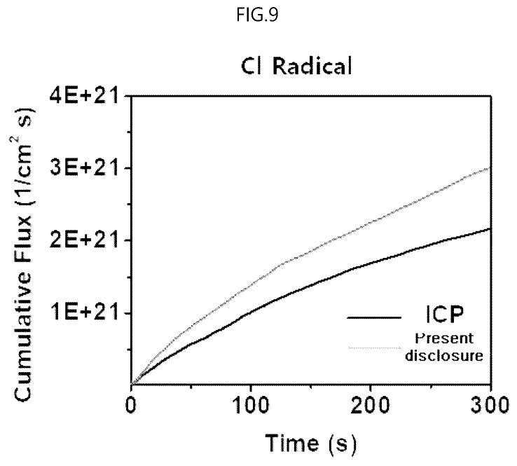

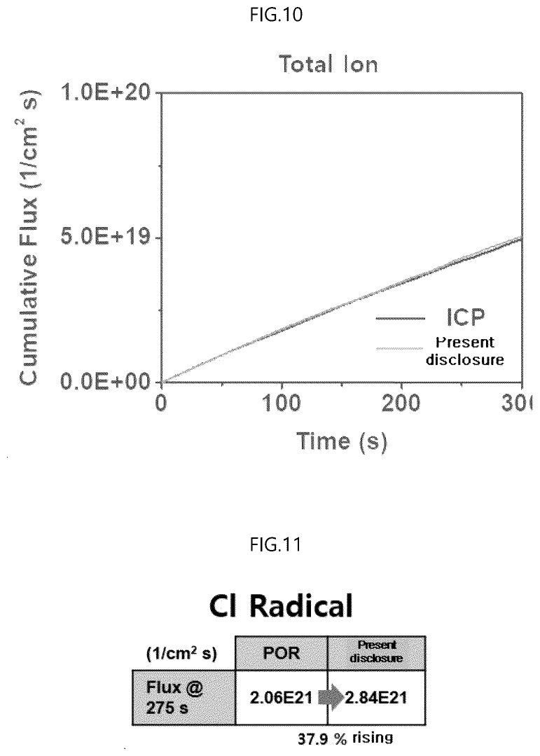

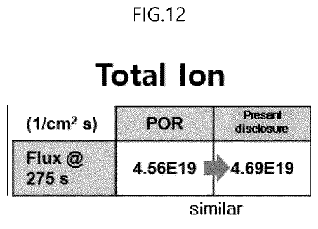

FIG. 9 is a graph comparing the cumulative flux of radicals at the etching front between the substrate treatment apparatus of the present disclosure and the conventional substrate treatment apparatus over time in the simulation. FIG. 10 is a graph comparing the cumulative flux of ions at the etching front between the substrate treatment apparatus of the present disclosure and the conventional substrate treatment apparatus over time in the simulation. FIG. 11 is a table comparing the cumulative flux of radicals at the etching front between the substrate treatment apparatus of the present disclosure and the conventional substrate treatment apparatus at the point in time when the simulation was conducted for 275 seconds in the simulation. FIG. 12 is a table comparing the cumulative flux of ions at the etching front between the substrate treatment apparatus of the present disclosure and the conventional substrate treatment apparatus at the point in time when the simulation was conducted for 275 seconds in the simulation.

Referring to FIGS. 9 to 12, the cumulative flux of ions at the etching front of the substrate treatment apparatus of the present disclosure is similar to the cumulative flux of ions at the etching front of the conventional substrate treatment apparatus. But, the cumulative flux of radicals at the etching front of the substrate treatment apparatus of the present disclosure is increased compared to the cumulative flux of radicals at the etching front of the conventional substrate treatment apparatus. This shows that the substrate treatment apparatus of the present disclosure can maintain the quantity of ions in the chamber 1000 at a small difference compared to the quantity of radicals, and control and increase the quantity of radicals

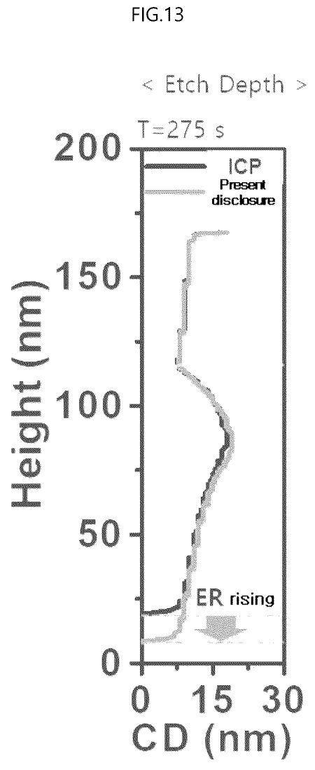

FIG. 13 is a graph comparing the etching depth between the substrate treatment apparatus of the present disclosure and the conventional substrate treatment apparatus at the point in time when the simulation was conducted for 275 seconds in the simulation.

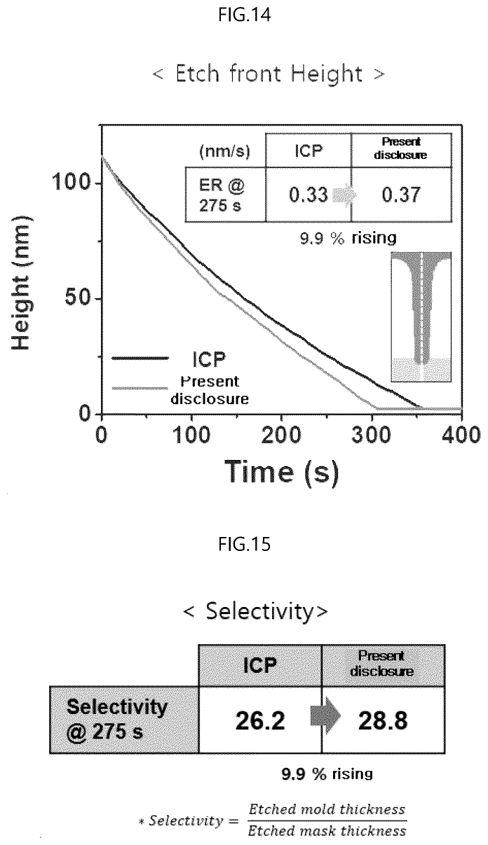

FIG. 14 is a table comparing the etching rate (ER) between the substrate treatment apparatus of the present disclosure and the conventional substrate treatment apparatus at the point in time when the simulation was conducted for 275 seconds, and a graph illustrating the time required for etching to a specific depth.

Referring to FIGS. 13 and 14, the etching rate of the substrate treatment apparatus of the present disclosure may be improved compared to the conventional substrate treatment apparatus.

FIG. 15 is a table comparing the etching selectivity between the substrate treatment apparatus of the present disclosure and the conventional substrate treatment apparatus at the point in time when the simulation was conducted for 275 seconds in the simulation.

Referring to FIG. 15, the etching selectivity of the substrate treatment apparatus of the present disclosure may be improved compared to the conventional substrate treatment apparatus.

As described above, the substrate treatment apparatuses 1, 1a, 1b, 1c, 1d, and 1e according to the example embodiments of the present disclosure can control the pressure and power in the radical control portion 4000 located outside the chamber 1000 to produce as many radicals as necessary and supply them into the chamber 1000, thereby maintaining the pressure inside the chamber 1000 at vacuum pressure while controlling the quantity of radicals for substrate processing. Therefore, when the substrate treatment apparatuses 1, 1a, 1b, 1c, 1d, and 1e of the present disclosure perform a process of etching the substrate 10, an ideal vertical etch profile can be implemented when etching a target object with a high aspect ratio.

The above-described contents are specific embodiments for carrying out the present disclosure. In addition to the above-described embodiments, the present disclosure will also include embodiments that are simply designed or can be easily changed. In addition, the present disclosure will also include technologies that can be easily modified and implemented using the embodiments. Therefore, the scope of the present disclosure should not be limited to the above-described embodiments, but should be determined by the claims described below as well as the equivalents of the claims of this disclosure.

While the present disclosure has been described with reference to embodiments thereof, it will be apparent to those of ordinary skill in the art that various changes and modifications can be made thereto without departing from the spirit and scope of the present disclosure as set forth in the following claims.

What is claimed is:

1. A plasma supply apparatus comprising:
a plasma supply portion configured to supply plasma into a chamber having a processing space in which a substrate is processed; and
a radical control portion configured to control a quantity of radicals in the processing space,
wherein the radical control portion includes:
a plasma chamber located outside the processing space and having a space in which plasma is generated;
a magnetron configured to generate microwaves;
a waveguide connected between the magnetron and the plasma chamber and configured to cause the microwaves to be transmitted between the magnetron and the plasma chamber;
a reaction gas supply portion configured to supply a reaction gas into the plasma chamber, and control an internal pressure of the plasma chamber; and
a radical supply connection portion connecting the plasma chamber and the chamber to be in communication with each other.

2. The plasma supply apparatus of claim 1,
wherein the plasma supply portion includes:
a gas supply portion configured to supply a treatment gas into the processing space; and
a plasma generation portion configured to convert the treatment gas into the plasma, and
wherein the plasma generation portion includes:
an antenna above the chamber; and
a source power supply configured to apply high-frequency power to the antenna.

3. The plasma supply apparatus of claim 2,
wherein the antenna includes:
a first antenna coil positioned to surround a central part of the substrate in the processing space when viewed from above; and
a second antenna coil surrounding an outer side of the first antenna coil.

4. The plasma supply apparatus of claim 3,
wherein the source power supply is configured to apply the high-frequency power having different frequencies to the first antenna coil and the second antenna coil.

5. The plasma supply apparatus of claim 3,
wherein the source power supply is configured to apply the high-frequency power having the same frequency to the first antenna coil and the second antenna coil.

6. The plasma supply apparatus of claim 1,
wherein the plasma supply portion includes:
a gas supply portion configured to supply a treatment gas into the processing space; and
a plasma generation portion configured to convert the treatment gas into the plasma,
wherein the plasma generation portion includes:
an upper electrode above the substrate in the processing space;
a lower electrode facing the upper electrode and positioned below the substrate; and
a source power supply configured to apply the high-frequency power to at least one of the upper electrode and the lower electrode, and
wherein the treatment gas is supplied between the upper electrode and the lower electrode.

7. The plasma supply apparatus of claim 1,
wherein the radical supply connection portion has one end connected to the plasma chamber and the other end connected to an upper wall of the chamber.

8. The plasma supply apparatus of claim 1,
wherein the radicals generated by the radical control portion are supplied from a plurality of positions on an upper wall of the chamber into the chamber.

9. The plasma supply apparatus of claim 8,
wherein the radicals generated by the radical control portion are supplied from a position of the upper wall of the chamber facing an edge area of the substrate within the processing space into the chamber.

10. A substrate treatment apparatus comprising:
a chamber having a processing space in which a substrate is processed;
a stage supporting the substrate in the processing space;
a plasma supply apparatus configured to supply plasma to the processing space and control a quantity of radicals in the processing space,
wherein the plasma supply apparatus includes:
a plasma supply portion configured to supply the plasma into the processing space; and
a radical control portion configured to control the quantity of the radicals in the processing space,
wherein the plasma supply portion includes:
a gas supply portion configured to supply a treatment gas into the processing space; and
a plasma generation portion configured to convert the treatment gas into the plasma,
wherein the plasma generation portion includes:
an antenna above the chamber; and
a source power supply configured to apply high-frequency power to the antenna,
wherein the radical control portion includes:
a plasma chamber located outside the processing space and having a space in which the plasma is generated;
a magnetron configured to generate microwaves;
a waveguide connected between the magnetron and the plasma chamber and configured to cause the microwaves to be transmitted between the magnetron and the plasma chamber;
a reaction gas supply portion configured to supply a reaction gas into the plasma chamber, and control an internal pressure of the plasma chamber; and
a radical supply connection portion connecting the plasma chamber and the chamber to be in communication with each other.

11. The substrate treatment apparatus of claim 10,
wherein the antenna includes:
a first antenna coil positioned to surround a central part of the substrate in the processing space when viewed from above; and
a second antenna coil surrounding an outer side of the first antenna coil.

12. The substrate treatment apparatus of claim 11,
wherein the source power supply is configured to apply the high-frequency power having different frequencies to the first antenna coil and the second antenna coil.

13. The substrate treatment apparatus of claim 11,
wherein the source power supply is configured to apply the high-frequency power having the same frequency to the first antenna coil and the second antenna coil.

14. The substrate treatment apparatus of claim 10,
wherein the radical supply connection portion has one end connected to the plasma chamber and the other end connected to an upper wall of the chamber.

15. The substrate treatment apparatus of claim 14,
wherein the radical supply connection portion is branched to have a plurality of the other ends, and
wherein the other ends are arranged spaced apart from each other on the upper wall of the chamber.

16. The substrate treatment apparatus of claim 10,
wherein the radicals generated by the radical control portion are supplied from a plurality of positions on an upper wall of the chamber into the chamber.

17. A substrate treatment apparatus comprising:
a chamber having a processing space in which a substrate is processed;
a stage supporting the substrate in the processing space;
a plasma supply apparatus configured to supply plasma to the processing space and control a quantity of radicals in the processing space,
wherein the plasma supply apparatus includes:
a plasma supply portion configured to supply the plasma into the processing space; and
a radical control portion configured to control the quantity of the radicals in the processing space,
wherein the plasma supply portion includes:
a gas supply portion configured to supply a treatment gas into the processing space; and
a plasma generation portion configured to convert the treatment gas into the plasma,
wherein the plasma generation portion includes:
an upper electrode above the substrate in the processing space;
a lower electrode facing the upper electrode and positioned below the substrate; and
a source power supply configured to apply high-frequency power to at least one of the upper electrode and the lower electrode,
wherein the treatment gas is supplied between the upper electrode and the lower electrode, and
wherein the radical control portion includes:
a plasma chamber located outside the processing space and having a space in which the plasma is generated;
a magnetron configured to generate microwaves;
a waveguide connected between the magnetron and the plasma chamber and configured to cause the microwaves to be transmitted between the magnetron and the plasma chamber;
a reaction gas supply portion configured to supply a reaction gas into the plasma chamber, and control an internal pressure of the plasma chamber; and
a radical supply connection portion connecting the plasma chamber and the chamber to be in communication with each other.

18. The substrate treatment apparatus of claim 17,
wherein the radical supply connection portion has one end connected to the plasma chamber and the other end connected to an upper wall of the chamber.

19. The substrate treatment apparatus of claim 18,
wherein the radical supply connection portion is branched to have a plurality of the other ends, and
wherein the other ends are arranged spaced apart from each other on the upper wall of the chamber.

20. The substrate treatment apparatus of claim 17,
wherein the radicals generated by the radical control portion are supplied from a plurality of positions on an upper wall of the chamber into the chamber.
